(19) United States
(12) Patent Application Publication
(10) Pub. No.: US 2016/0227662 A1
(43) Pub. Date: Aug. 4, 2016

(54) ELECTRONIC DEVICE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YU-MING XIAO, Wuhan (CN); LIANG-CHIN WANG, New Taipei (TW); ZAN LI, Wuhan (CN); CHUAN LIN, Wuhan (CN)

(21) Appl. No.: 14/684,898

(22) Filed: Apr. 13, 2015

(30) Foreign Application Priority Data
Jan. 29, 2015 (CN) 201510045923.3

(51) Int. Cl. H05K 5/03; H05K 5/02; H05K 9/00; H05K 5/00

(52) U.S. Cl. CPC H05K 5/03; H05K 5/0004; H05K 5/0221; H05K 9/0007

(57) ABSTRACT

An electronic device includes a chassis, a circuit board received in the chassis, and a cover coupled to the chassis. The chassis defines an opening and includes a first sidewall and a second sidewall. The cover includes a base plate, a first side plate, and a second side plate. The base plate is configured to cover the opening. The first side plate extends from the base plate and covers the first sidewall. The second side plate is mounted to the second sidewall. The first sidewall and the second sidewall are located at two opposite sides of the opening. The first side plate and the second side plate are located at two opposite sides of the base plate. The first side plate and the base plate are rotatable relative to the second side plate to enable access to the opening.

### CROSS-REFERENCE TO RELATED APPLICATIONS

This application claims priority to Chinese Patent Application No. 201510045923.3 filed on Jan. 29, 2015, the contents of which are hereby incorporated by reference.

### FIELD

The subject matter herein generally relates to an electronic device.

### BACKGROUND

An electronic device generally includes a chassis and a plurality of components. The chassis generally includes a chassis body to receive the components and a cover configured to cover the components, and the cover is usually secured to the chassis body by a number of fasteners or slidably mounted to the chassis body.

### BRIEF DESCRIPTION OF THE DRAWINGS

Implementations of the present technology will now be described, by way of example only, with reference to the attached figures.

FIG. 1 is an exploded, isometric view of an electronic device in accordance with a first embodiment.

FIG. 2 is an assembled, isometric view of the electronic device of the FIG. 1, wherein an opening of a chassis is closed.

FIG. 3 is similar to FIG. 2, but the opening is shown.

FIG. 4 is an exploded, isometric view of an electronic device in accordance with a second embodiment.

FIG. 5 is an assembled, isometric view of the electronic device of FIG. 4.

FIG. 6 is an exploded, isometric view of an electronic device in accordance with a third embodiment.

FIG. 7 is an assembled, isometric view of the electronic device of FIG. 7.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

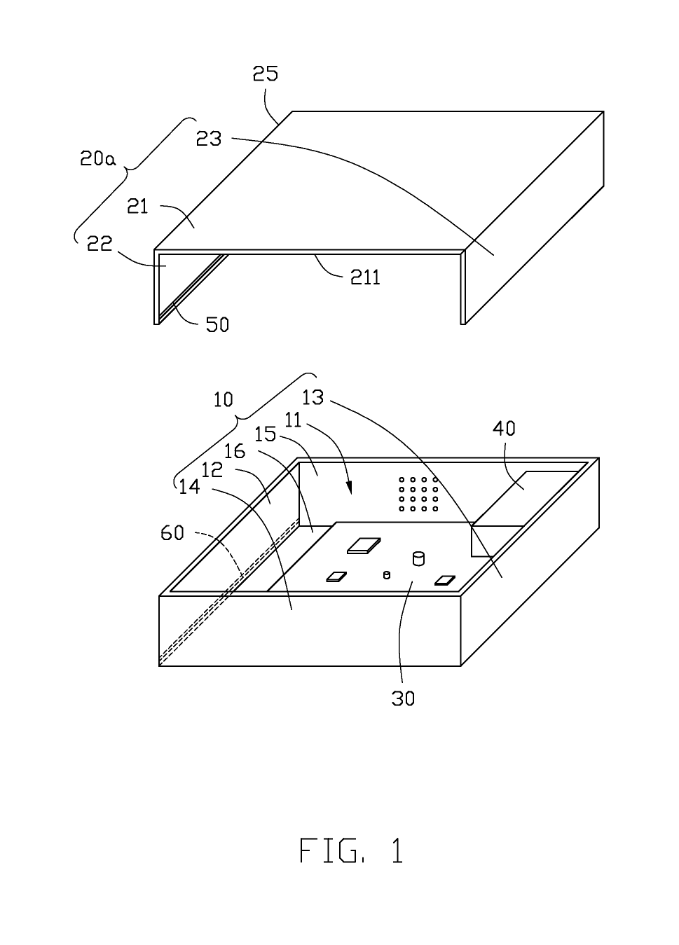

FIG. 1 illustrates a first embodiment of an electronic device can include a chassis 10, a cover 20a configured to be coupled to the chassis 10, a circuit board 30 received in the chassis 10, and a power supply 40 mounted in the chassis 10 and electronically coupled to the circuit board 30. The circuit board 30 includes a plurality of electronic components, such as control process units.

The chassis 10 defines an opening 11 and can include a first sidewall 12, a second sidewall 13, a front wall 14, a second wall 15, and a bottom wall 16. The circuit board 30 is secured on the bottom wall 16. The first sidewall 12 and the second sidewall 13 extend from two opposite sides of the bottom wall 16 and are parallel to each other. The front wall 14 and the rear wall 15 extend perpendicularly from two another opposite sides of the bottom wall 16 and are parallel to each other. The rear wall 15 defines a plurality of vents. The opening 11 is defined by the first sidewall 12, the second sidewall 13, a front wall 14, and a rear wall 15. The circuit board 30 and the power supply 40 can be inserted through the opening 11 to be mounted in the chassis 10. In at least one embodiment, the chassis 10 is made of metal.

The cover 20a can include a base plate 21, a first side plate 22, and a second side plate 23. The base plate 21 is configured to cover the opening 11. The first side plate 22 and the second side plate 23 are located at two opposite sides of the base plate 21. The cover 20a further includes a shielding layer 211 located on an inner surface of the base plate 21. The shielding layer 211 is made of metal. The first side plate 22 and the second side plate 23 extend from the base plate 21, and the first side plate 22 and the second side plate 23 are rotatable relative to the base plate 21. The cover 20a is made of paper, a plurality of parallel folds 25 is pressed in the cover 20a, and the cover 20a is foldable along the plurality of folds 25 to form the base plate 21, the first side plate 22, and the second side plate 23.

The electronic device further includes a mounting member 50 and an engaging member 60 configured to engage with the mounting member 50. The mounting member 50 is attached to an inner surface of the first side plate 22 adjacent to a free end. The engaging member 60 is attached to an outer surface of the first sidewall 12 and adjacent to the bottom wall 16. The mounting member 50 can be a magnetic strip, a hook, or a slot. The engaging member 60 corresponding to the mounting member 50 can be a magnetic strip, a slot or a hook.

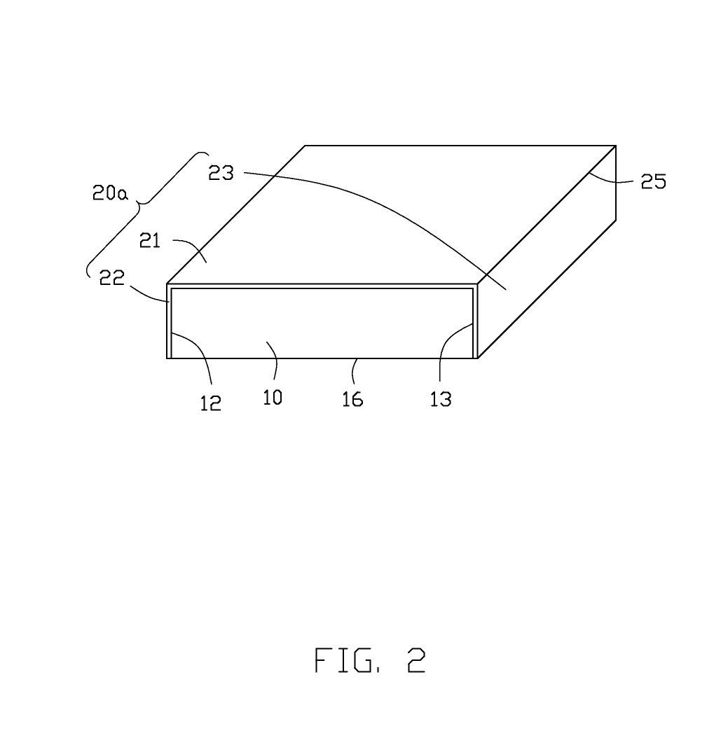

FIG. 2 illustrates the cover 20a is coupled to the chassis 10. The second side plate 23 is fixed on the second sidewall 13, and the mounting member 50 is engaged with the engaging member 60. The cover 20a is mounted to the chassis 10. The first side plate 22 covers the first sidewall 12, the second side plate 23 covers the second sidewall 13, and the opening 11 is closed by the base plate 21. The shielding layer 211 can prevent electromagnetic interference generated from the plurality of electronic components from egression from the chassis 10 via the opening 11. The first side plate 22 and the second side plate 23 are substantially perpendicular to the base plate 21 and parallel to each other. The second side plate 23 can be secured to the second sidewall 13 by pasting, locking, magnetic attraction, and so on.

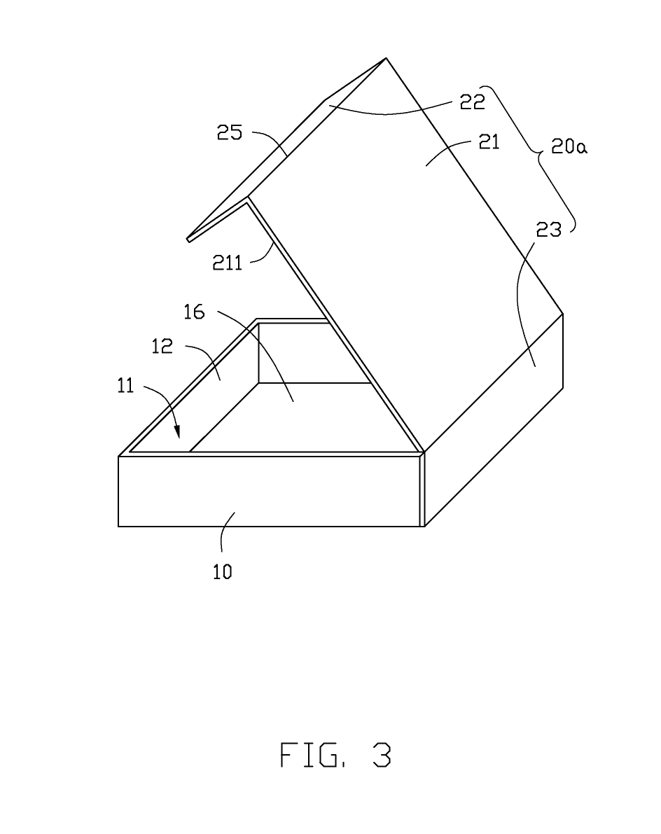

FIG. 3 illustrates the cover 20a is opened. When the circuit board 30 and the power supply 40 need to be mounted in or removed from the chassis 10, the first side plate 12 is moved to disengage the mounting member 50 from the engaging member 60. The first side plate 22 and the base plate 21 rotate relative to the second side plate 23, and the opening 11 is shown. The first side plate 22 is rotatable relative to the base plate 21.

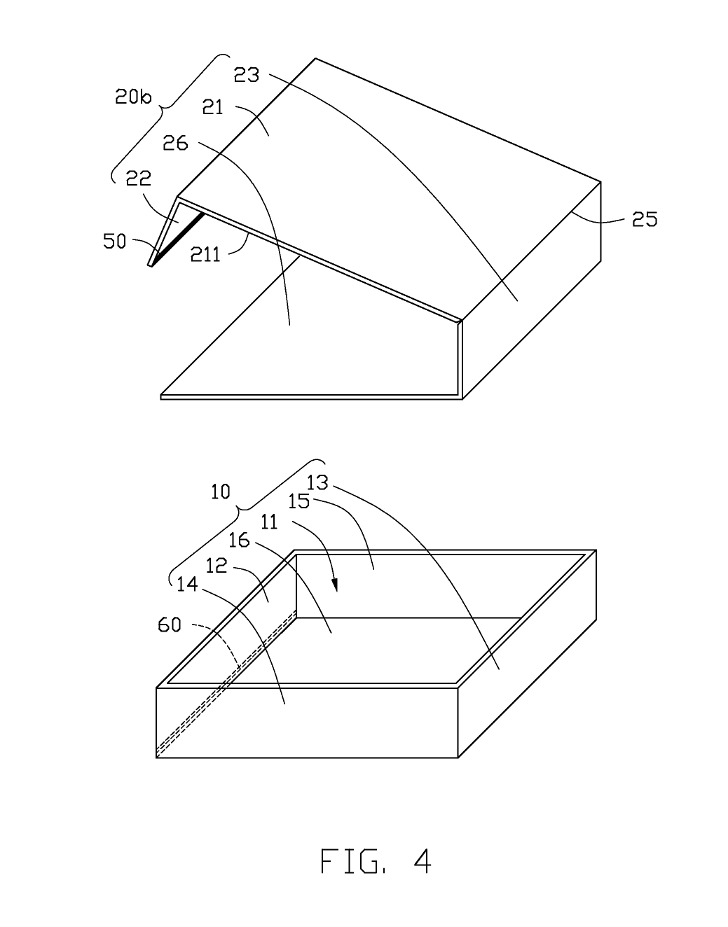

FIG. 4 illustrates a second embodiment of an electronic device includes the chassis 10, a cover 20b, the circuit board 30, the power supply 40, the mounting member 50, and the engaging member 60. The cover 20b is similar to the cover 20a. The difference between the cover 20b and the cover 20a is the cover 20b further includes a bottom plate 26 extending from the second side plate 23, and the bottom plate 26 and the base plate 21 are located at two opposite sides of the second side plate 23.

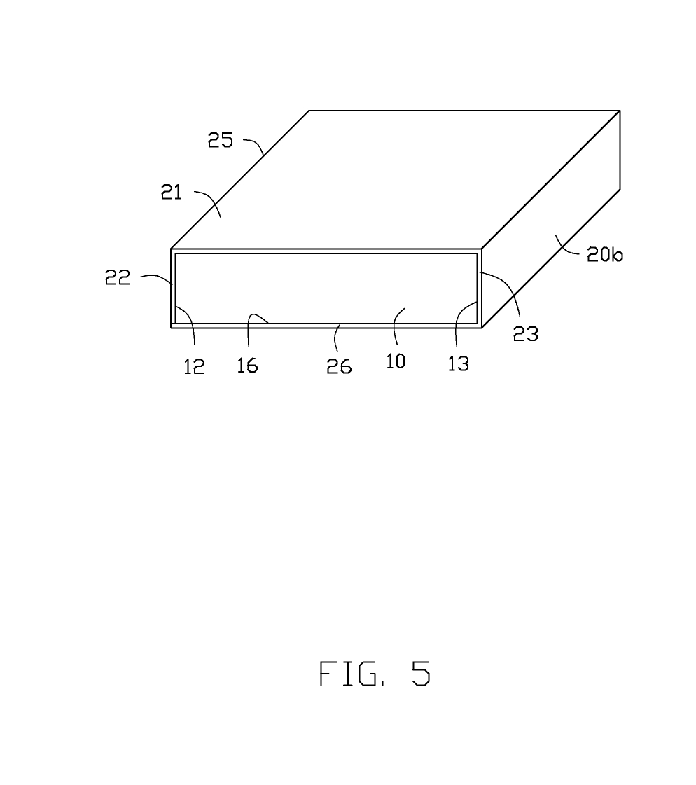

FIG. 5 illustrates the second embodiment of the cover 20b is coupled to the chassis 10. The way of opening and closing the cover 20b in the second embodiment is similar to the way in the first embodiment. The difference is the bottom plate 26 is fixed on the bottom wall 16 by pasting, locking, magnetic attraction, and so on. The cover 20b surrounds the chassis 10.

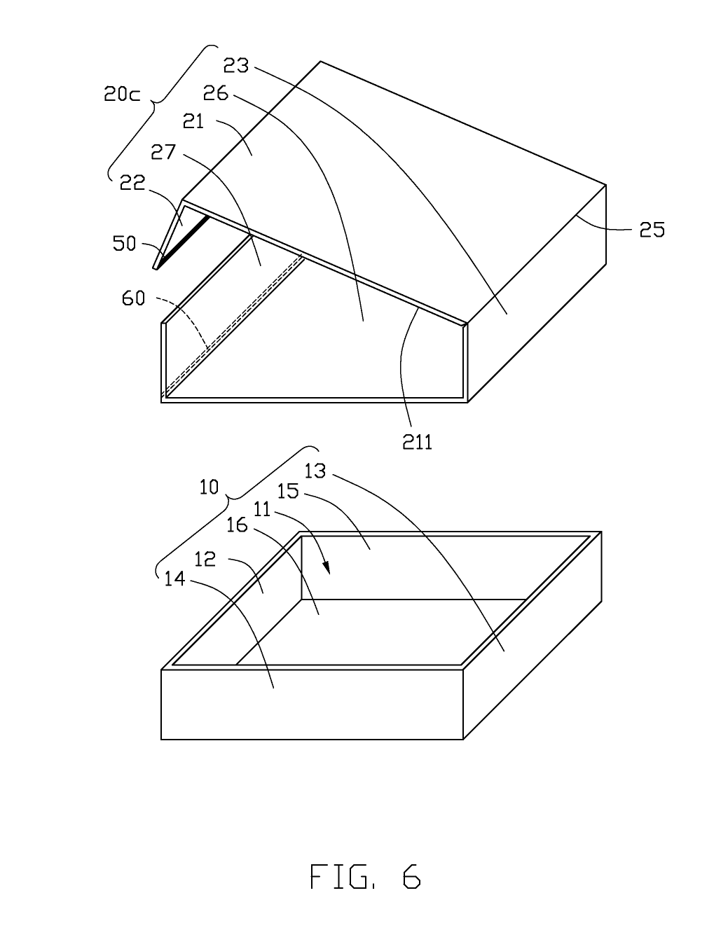

FIG. 6 illustrates a third embodiment of the electronic device includes the chassis 10, a cover 20c, the circuit board 30, the power supply 40, the mounting member 50, and the engaging member 60. The cover 20c is similar to the cover 20b. The difference between the cover 20c and the cover 20b is the cover 20c further includes a third plate 27 extending from the second side plate 23. The third side plate 27 and the second side plate 23 are located at two opposite sides of the bottom plate 26.

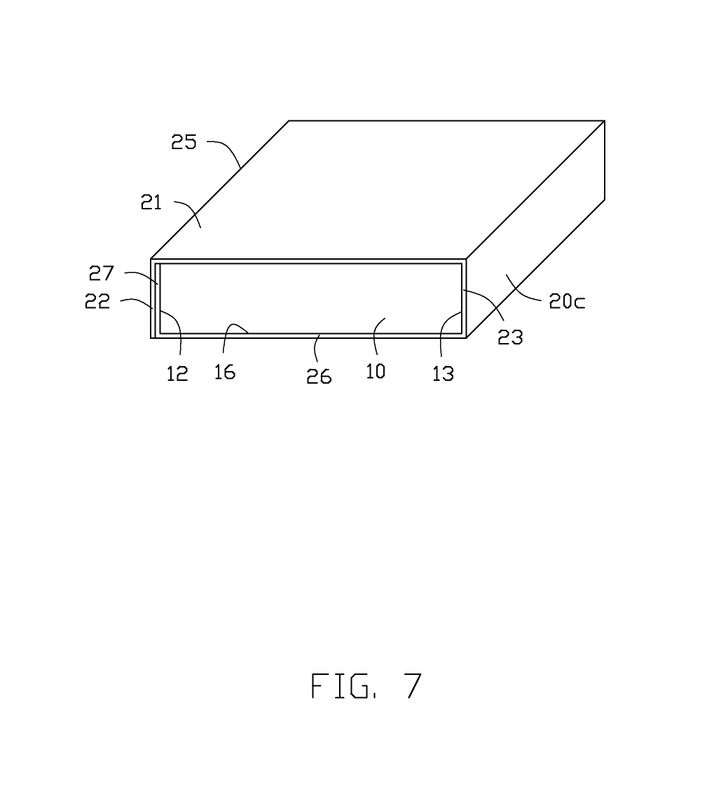

FIG. 7 illustrates the cover 20c is coupled to the chassis 10. The mounting member 50 is attached to an inner surface of the first side plate 22, and the engaging member 40 is attached to an outer surface of the third side plate 27 and adjacent to a free end of the third side plate 27. The bottom plate 26 is fixed on the bottom wall 16, the second side plate 23 is fixed on the second sidewall 13, the third side plate 27 is fixed on the first sidewall 22, and the cover 20c is mounted to the chassis 10.

The first side plate 22 and the base plate 21 are rotatable to engage the mounting member 50 with the engaging member 60. The opening 11 is covered by the base plate 21, the first side plate 22 covers the third plate 27, and the chassis 10 is surrounded by the cover 20c. The third plate 27 and the second side plate 23 are substantially perpendicular to the bottom plate 26 and parallel to each other. The base plate 21 and the bottom plate 27 are substantially parallel to each other.

The embodiments shown and described above are only examples. Many details are often found in the art such as the other features of an electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An electronic device comprising:
a chassis defining an opening and comprising a first sidewall and a second sidewall;
a circuit board configured to be inserted through the opening and received in the chassis; and
a cover coupled to the chassis comprising:
a base plate configured to cover the opening;
a first side plate extending from the base plate and covering the first sidewall; and
a second side plate mounted to the second sidewall;
wherein the first sidewall and the second sidewall are located at two opposite sides of the opening, the first side plate and the second side plate are located at two opposite sides of the base plate, and the first side plate and the base plate are rotatable relative to the second side plate to enable access to the opening.

2. The electronic device of claim 1, wherein the chassis body is made of metal, and the cover is made of paper.

3. The electronic device of claim 2, wherein the cover further comprises a shielding layer fixed to the base plate to prevent electromagnetic interference generated from electronic components of the circuit board from egression from the chassis via the opening.

4. The electronic device of claim 2, wherein the first side plate is substantially perpendicular to the base plate.

5. The electronic device of claim 2, wherein the cover further comprises a bottom plate extending from the side plate, the base plate and the bottom plate are located at two opposite sides of the second side plate; the chassis further comprises a bottom wall connected to the bottom plate, the bottom wall is fix on the bottom plate, and the chassis is covered around by the cover.

6. The electronic device of claim 5, further comprising a mounting member attached to an inner surface of the first side plate and an engaging member attached to an outer surface of the first sidewall, and the mounting member is engaged with the engaging member.

7. The electronic device of claim 5, wherein the second side plate is fixed to the first sidewall by pasting, locking, or magnetic attraction.

8. The electronic device of claim 5, wherein the second side plate extends from the base plate and is substantially perpendicular to the bottom plate.

9. The electronic device of claim 5, wherein the cover further comprises a third side plate mounted on the first sidewall, the third plate and the second plate are located two opposite sides of the bottom plate, and the first side plate is mounted on the third side plate.

10. The electronic device of claim 9, wherein the third side plate extends perpendicularly from the bottom plate and is substantially parallel to the second side plate.

11. An electronic device comprising:
a chassis configured to receive a circuit board and defining an opening; and
a cover made of paper and pressed a plurality of parallel folds;
wherein the cover is foldable along the plurality of folds to cover around the chassis to enable access to the opening.

12. The electronic device of claim 11, further comprising a mounting member attached to the cover and an engaging member attached to the chassis, and the mounting member is engaged with the engaging member.

13. The electronic device of claim 11, further comprising a mounting member and an engaging member, the mounting member and the engaging member are attached to the cover and located at two opposite end of the cover, and the mounting member is engaged with the engaging member.

14. The electronic device of claim 11, wherein the cover further comprising a shielding layer covering the opening to prevent electromagnetic interference generated from electronic components of the circuit board from egression from the chassis via the opening.

15. The electronic device of claim 11, wherein the cover is mounted to the chassis by pasting, locking, or magnetic attraction.
